(19) United States
(12) Patent Application Publication
(10) Pub. No.: US 2010/0244074 A1
(43) Pub. Date: Sep. 30, 2010

(54) SEMICONDUCTOR LIGHT-EMITTING DEVICE AND METHOD OF MANUFACTURING THE SAME

(75) Inventors: Takafumi Oka, Tokyo (JP); Shinji Abe, Tokyo (JP); Kazushige Kawasaki, Tokyo (JP); Junichi Horie, Tokyo (JP); Hitoshi Sakuma, Tokyo (JP)

Correspondence Address: LEYDIG VOIT & MAYER, LTD, 700 THIRTEENTH ST. NW, SUITE 300, WASHINGTON, DC, 20005-3960, US

(73) Assignee: MITSUBISHI ELECTRIC CORPORATION, Tokyo (JP)

(21) Appl. No.: 12/716,399

(22) Filed: Mar. 3, 2010

(30) Foreign Application Priority Data
Mar. 30, 2009 (JP) 2009-082033

(51) Int. Cl. H01L 33/58

(52) U.S. Cl. 257/98; 438/31; 257/E33.068

(57) ABSTRACT

A semiconductor light-emitting device and a manufacturing method are provided, in which a metal film is deposited with positional differences between edges of an insulating film and the metal film, opposite a ridge waveguide top face, utilizing an overhanging-shaped resist pattern. An opening through the insulating film is extended in width without another masking step by etching the insulation film on the ridge waveguide top face, using the metal film as a mask. The contact area between a p-side electrode and a p-type contact layer is increased and operating voltage of the semiconductor light-emitting device is reduced.

### BACKGROUND OF THE INVENTION

1. Field of the Invention

The present invention relates to a semiconductor light-emitting device and a manufacturing method therefor, more particularly, to a ridge-type semiconductor laser device and a manufacturing method therefor.

2. Description of the Prior Art

A conventional method of manufacturing a ridge-type semiconductor laser device includes a step of forming an overhang-shaped resist on the top face of a p-type GaN contact layer formed in the ridge top of an (Al, Ga, In) N based compound semiconductor, so as to partially expose the contact layer top face; a step of forming an insulation film to cover the resist and the exposed top face portion of the p-contact layer; a step of lifting off the insulation film formed on the resist, by removing the resist; and a step of forming a p-side electrode on the opened face of the p-contact layer and the insulation film; thereby to improve yields in the lift-off step (see, for example, JP Unexamined Patent Publication No. 2007-27164A (FIG. 2)).

In such above-mentioned conventional manufacturing methods for semiconductor light-emitting devices, since the top face of the p-type contact layer formed in the ridge top is partially covered with the insulation film, the contact area between the p-contact layer and the p-side electrode is reduced, resulting in a problem of increasing the operating voltage of a semiconductor light-emitting device. Particularly in a blue-violet semiconductor light-emitting device, since a nitride semiconductor such as a GaN one used for the p-type contact layer is higher in contact resistance compared with a III-V compound semiconductor such as a GaAs compound one used for the p-type contact layer of a red semiconductor light-emitting device, there has been a problem that the blue-violet semiconductor light-emitting device significantly increases in its operating voltage owing to reduction of the contact area between the p-type contact layer and the p-side electrode.

### SUMMARY OF THE INVENTION

The present invention is addressed to resolve the above-mentioned problem, and provides a method that is capable of easily manufacturing a semiconductor light-emitting device that operates at a lower voltage, by increasing the contact area between the p-type contact layer and the p-side electrode. The invention also provides a lower-voltage operable semiconductor light-emitting device.

A method of manufacturing a semiconductor light-emitting device according to the present invention includes: a semiconductor layer forming step of forming successively on a substrate, a first conductivity type semiconductor layer, an active layer, and a second conductivity type semiconductor layer; a resist forming step of forming a resist pattern having an overhang shape in cross section in a predetermined position on the second conductivity type semiconductor layer; a ridge forming step of forming a ridge waveguide in the second conductivity type semiconductor layer by etching the second conductivity type semiconductor layer using the resist pattern as a mask; an insulation film forming step of forming, on the resist pattern and the second conductivity type semiconductor layer, an insulation film having a first opening formed on a portion of the ridge waveguide top face using the resist pattern; a metal film forming step of forming on the insulation film a metal film having a second opening whose width is larger than that of the first opening; a lift-off step of lifting off, by removing the resist pattern, portions of the insulation film and the metal film which portions have been formed on the resist pattern; an insulation film etching step of etching by using the metal film as a mask, edges of the insulation film that have been formed on the ridge waveguide; and a metal electrode forming step of forming a metal electrode on the metal film, and on the second conductivity type semiconductor layer through the first and the second openings.

A semiconductor light-emitting device according to the invention includes: a substrate; a first conductivity type semiconductor layer formed on the substrate; an active layer formed on the first conductivity type semiconductor layer; a second conductivity type semiconductor layer formed on the active layer and having a ridge waveguide that projects upwards with respect to the active layer; an insulation film formed on the second conductivity type semiconductor layer and having a first opening that opens on the top face of the ridge waveguide; a metal film formed on the insulation film and having a second opening that communicates with the first opening and whose width is narrower than that of the first opening; and a metal electrode electrically connected with the second conductivity type semiconductor layer through the first and the second openings.

According to the present invention, the contact area between the p-type contact layer and the p-side electrode can be readily increased, so that a lower-voltage operable semiconductor light-emitting device can be realized.

### BRIEF DESCRIPTION OF THE DRAWINGS

FIG. 1 is a cross sectional view illustrating a configuration of a semiconductor light-emitting device in Embodiment 1 of the present invention;

FIG. 2 is a cross sectional view illustrating a step of manufacturing the semiconductor light-emitting device in Embodiment 1;

FIG. 3 is a cross sectional view illustrating a step of manufacturing the semiconductor light-emitting device in Embodiment 1;

FIG. 4 is a cross sectional view illustrating a step of manufacturing the semiconductor light-emitting device in Embodiment 1;

FIG. 5 is a cross sectional view illustrating a step of manufacturing the semiconductor light-emitting device in Embodiment 1;

FIG. 6 is a cross sectional view illustrating a step of manufacturing the semiconductor light-emitting device in Embodiment 1;

FIG. 7 is a cross sectional view illustrating a configuration of a semiconductor light-emitting device in Embodiment 2 of the invention; and

FIG. 8 is a cross sectional view illustrating a configuration of a semiconductor light-emitting device in Embodiment 3 of the invention.

### DESCRIPTION OF THE PREFERRED EMBODIMENTS

### Embodiment 1

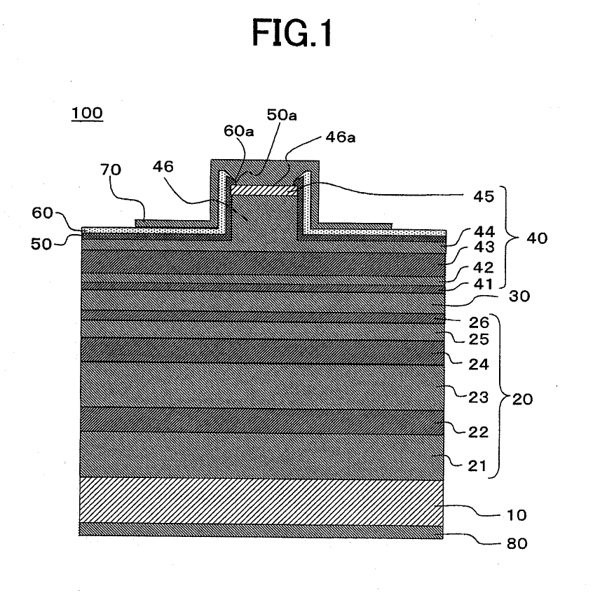

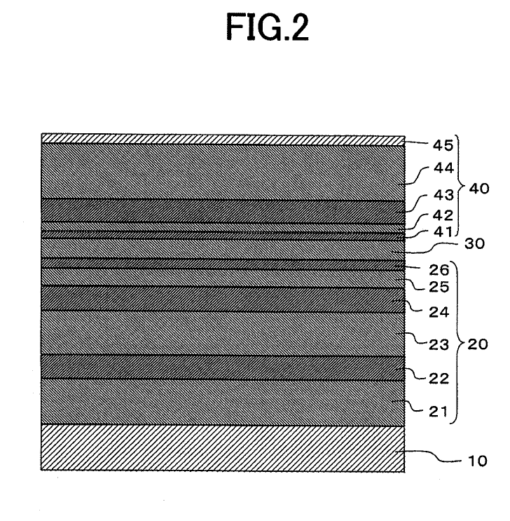

FIG. 1 is a cross sectional view illustrating a configuration of a semiconductor light-emitting device in Embodiment 1 of the present invention. FIGS. 2 to 6 are cross sectional views illustrating manufacturing steps for the semiconductor light-emitting device in Embodiment 1.

First, the configuration of the semiconductor light-emitting device in Embodiment 1 will be described with reference to FIG. 1.

A semiconductor laser device 100 shown in FIG. 1 is the semiconductor light-emitting device. On an n-type GaN substrate 10, an n-type (first conductivity type) semiconductor layer 20 is formed that is composed of successive layers of an n-type buffer layer 21 of 1,000 nm thick GaN, an n-type clad layer 22 of 400 nm thick Al_{0.07}Ga_{0.93}N, an n-type clad layer 23 of 1,000 nm thick Al_{0.045}Ga_{0.955}N, an n-type clad layer 24 of 300 nm thick Al_{0.015}Ga_{0.985}N, an n-type light-guide layer 25 of 80 nm thick GaN, and an n-side separate-confinement heterostructure (SCH) layer 26 of 30 nm thick In_{0.02}Ga_{0.98}. The above layers 21 to 26 constituting the n-semiconductor layer 20 are each doped with Si as an n-type impurity.

On the first conductivity type semiconductor layer 20, an active layer 30 is formed. The active layer 30 has a double quantum-well structure that is successively formed of an n-type well layer of 5 nm thick In_{0.12}Ga_{0.88}N, an n-type barrier layer of 8 nm thick In_{0.02}Ga_{0.98}N, and an n-type well layer of 5 nm thick In_{0.12}Ga_{0.88}N.

On the active layer 30, a p-type (second conductivity type) semiconductor layer 40 is further formed that is composed of successive layers of a p-side SCH layer 41 of 30 nm thick In_{0.02}Ga_{0.98}N, a p-type electron-barrier layer 42 of 20 nm thick Al_{0.2}Ga_{0.8}N, a p-type light-guide layer 43 of 100 nm thick GaN, a p-type clad layer 44 of 500 nm thick Al_{0.07}Ga_{0.93}N, and a p-type contact layer 45 of 20 nm thick GaN. The layers 41 to 45 constituting the p-semiconductor layer 40 are each doped with Mg as a p-type impurity.

Here, in the p-clad layer 44 and the p-contact layer 45 among the layers constituting the p-semiconductor layer 40, a stripe ridge waveguide 46 is formed. The ridge waveguide 46 is located at an approximately widthwise middle portion of the laser diode, and extends over between both cleavage end faces i.e., the cavity ends of the laser diode. In this embodiment, the longitudinal length of the ridge waveguide 46 i.e., the length of the cavity is designed to be 1,000 pm, the ridge width orthogonal to the longitudinal direction of the ridge waveguide to be 1.5 μm, and the height of the ridge waveguide 46 to be 0.5 μm. However, the width may be varied from 1 μm to several dozens μm depending upon specifications.

On the outer surfaces of the p-semiconductor layer 40, formed is an insulation film 50 having a thickness of 200 nm, through which an opening 50a is formed on a central portion of the ridge waveguide top face 46a. In this embodiment, the insulation film 50 is formed of SiO₂.

On the insulation film 50, formed is a metal film 60 having a thickness of 70 nm, through which a second opening 60a is formed above the top face 46a of the ridge waveguide 46 to communicate with the first opening 50a. The first opening 50a here self-adjusts its width to the second opening 60a, to have substantially the same width. The metal film 60 is formed, for example, of an Au containing metallic material.

A p-side electrode 70 is formed on the metal film 60. The p-side electrode 70 is electrically connected with the p-contact layer 45 via the second opening 60a formed through the metal film 60 and the first opening 50a formed through the insulation film 50, so that an ohmic contact is formed between the p-contact layer 45 and the p-side electrode 70. The p-side electrode 70 is formed of palladium (Pd), for example, in a single layer structure of Pd, a multi-layer structure of Pd/Ta, or a multi-layer structure of Pd/Ta/Pd, in order to reduce the contact resistance with the p-GaN contact layer 45.

On the rear surface of the n-GaN substrate 10, an n-side electrode 80 is formed that is composed of successive layers of Ti, Pt, and Au films.

Next, a method of manufacturing the semiconductor light-emitting device in Embodiment 1 will be described with reference to FIGS. 2 to 6.

### Semiconductor Layer Forming Step

First, in the step shown in FIG. 2, the n-type semiconductor layer 20 is formed on the n-type GaN substrate 10 whose surfaces has been pre-cleaned by thermal cleaning or the like, by successively depositing using, for example, metal organic chemical vapor deposition (MOCVD), the n-type buffer layer 21 of 1 μm thick GaN, the n-type clad layer 22 of 400 nm thick Al_{0.07}Ga_{0.93}N, the n-type clad layer 23 of 1,000 nm thick Al_{0.045}Ga_{0.955}N, the n-type clad layer 24 of 300 nm thick Al_{0.015}Ga_{0.985}N, the n-type light-guide layer 25 of 80 nm thick GaN, and the n-side separate-confinement heterostructure (SCH) layer 26 of 30 nm thick In_{0.02}Ga_{0.98}.

Then, after the active layer 30 is deposited on the n-semiconductor layer 20 by MOCVD or the like, the p-type semiconductor layer 40 is formed by successively depositing on the active layer 30 by MOCVD or the like, the p-side SCH layer 41 of 30 nm thick In_{0.02}Ga_{0.98}N, the p-type electron-barrier layer 42 of 20 nm thick Al_{0.2}Ga_{0.8}N, the p-type light-guide layer 43 of 100 nm thick GaN, the p-type clad layer 44 of 500 nm thick Al_{0.07}Ga_{0.93}N, and the p-type contact layer 45 of 20 nm thick GaN.

### Resist Forming Step

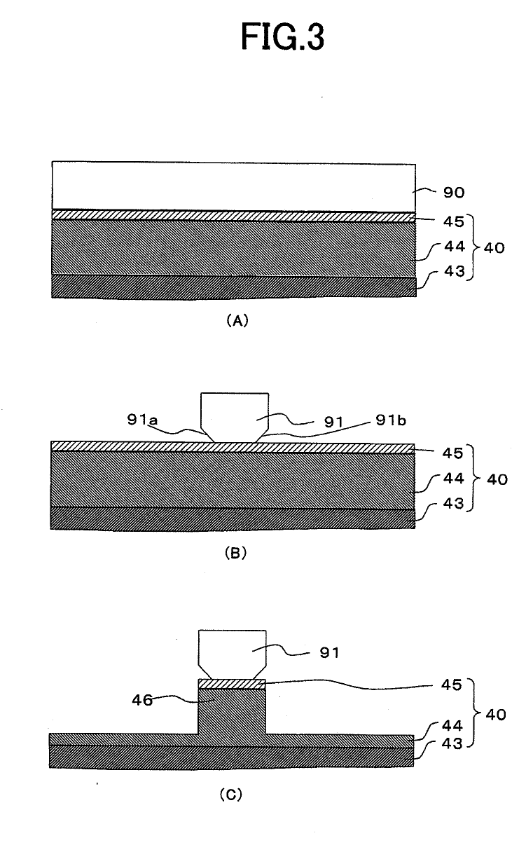

Next, in the step shown in FIG. 3A, the upper surface of the p-semiconductor layer 40, i.e., the entire surface of the p-contact layer 45 is coated with an image reversal resist 90 by a spin coating technique. Then, a portion of the resist corresponding to the shape of the ridge waveguide 46 is left intact and the other portions are removed in the photolithography step shown in FIG. 3B. Using such an image reversal resist for the resist in this step can form a resist pattern 91 that has an overhang shape in cross section. The resist pattern of overhang shape in cross section refers to that the overhangs 91a and 91b are formed in its both side portions near the p-contact layer 45 to create spaces between the overhangs 91a and 91b, and the p-contact layer 45.

### Ridge Forming Step

Then, in the step shown in FIG. 3C, the p-contact layer 45 and the p-clad layer 44 are partially etched by reactive ion etching (RIE) using the resist pattern 91 as a mask, to form the ridge waveguide 46 in the p- p-semiconductor layer 40. The etching depth here is designed to be 500 nm.

### Insulation Film Forming Step

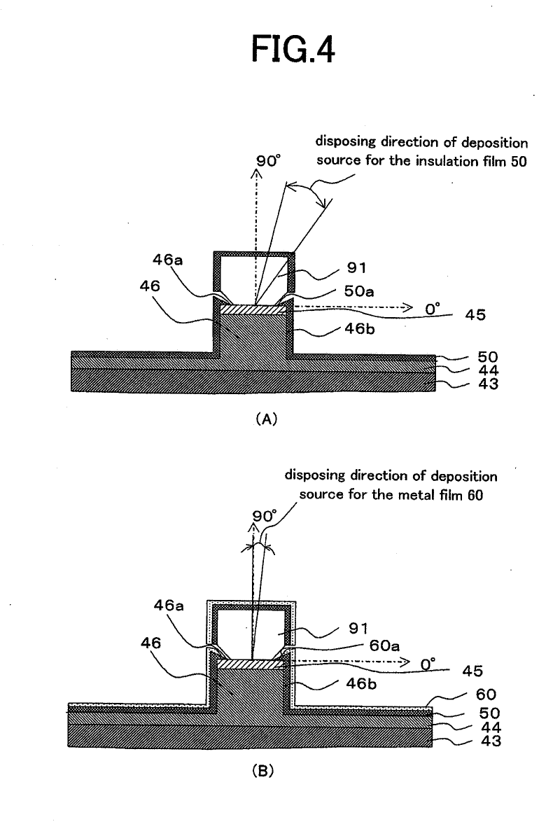

Next, in the step shown in FIG. 4A, the insulation film 50 of 200 nm thick SiO₂ is deposited on the exposed surfaces of the p-semiconductor layer 40 and the surface of the resist pattern 91 by vacuum deposition. Here, defining a coordinate such that the centre of the top face 46a of the ridge waveguide 46 serves as its origin point O, and the widthwise direction of the ridge waveguide 46 as 0° and the normal direction of the ridge waveguide top face 46a, i.e., the direction of depositing the n-semiconductor layer 20, the active layer 30, and the p-semiconductor layer 40 as 90°, the deposition source of SiO₂ is disposed in a direction ranging from 50° to 80°, more preferably from 58° to 78°. By disposing the deposition source of SiO₂ in such angular range and carrying out the SiO₂ deposition while rotating the substrate 10, SiO₂ can be deposited even into both side spaces between the p-semiconductor layer 40 and the overhang-shaped resist 91, whereby the SiO₂ film is deposited so as to cover the corners of the top face 46a of the waveguide 46.

While FIG. 4A shows a relative positional relationship between the top face 46a of the ridge waveguide 46 and the deposition source of SiO₂, the deposition is in practice carried out in a face down manner such that the top face 46a of the ridge waveguide 46 is directed downwardly.

The insulation film 50, although it can also be formed by sputtering, is formed preferably by vapor deposition. If using sputtering, by disposing the sputter source in a direction of approximately 90° with respect to the origin point O, SiO₂ can also be deposited into both side spaces between the p-semiconductor layer 40 and the resist 91.

### Metal Film Forming Step

In the subsequent step shown in FIG. 4B, the metal film 60 of Au is deposited on the insulation film 50 by vacuum deposition. In this step, the overhang-shaped resist pattern 91 used in the insulation film forming step is utilized without modification. Here, defining a coordinate such that the center of the top face 46a of the ridge waveguide 46 serves as its origin point O, and the widthwise direction of the ridge waveguide 46 as 0° and the normal direction of the top face 46a of the ridge waveguide 46, i.e., the direction of depositing the n-semiconductor layer 20, the active layer 30, and the p-semiconductor layer 40 as 90°, the deposition source for the metal film 60 is disposed in a direction ranging from 80° to 90°, more preferably from 85° to 90°. By disposing the deposition source for the metal film 60 in such angular range and depositing from the deposition source while rotating the substrate 10, the metal film 60 can be deposited even on edges of the insulation film 50 so that positional differences are formed between the edges of the insulation film 50 and those of the metal film 60 above the waveguide top face 46a. In. particular, since the insulation film 50 has been deposited also on the side faces of the resist pattern 91 in the above-mentioned insulation film forming step, the deposition of the metal film 60 can be suppressed in the metal film forming step to enter into the space between the overhangs 91a, 91b of the resist pattern 91 and the ridge waveguide top face 46a, allowing the positional differences to be formed between the edges of the insulation film 50 and those of the metal film 60.

While FIG. 4B also shows a relatively positional relationship, as FIG. 4A, between the top face 46a of the ridge waveguide 46 and the deposition source for the metal film 60, the deposition is in practice carried out in a face down manner such that the ridge waveguide top face 46a is directed downwardly.

At that time, it is desirable that the width of the second opening 60a formed through the metal film 60 be approximately the same as that of the ridge waveguide 46. Note that “approximately the same” implies that the opening width is within a range of about ±10% with respect to the width of the ridge waveguide 46.

In addition, the positional arrangements of the deposition sources for the insulation film 50 and the metal film 60 are not limited to the above-mentioned angular ranges, because the positional differences can be formed between the edges of the metal film 60 and those of the insulation film 50 by setting larger the angle between the ridge waveguide top face 46a and the deposition source for the metal film 60 than that between the ridge waveguide top face 46a and the deposition source for the insulation film 50 in the insulation film and the metal film forming steps. As defined above, “angles between the ridge waveguide top face and the deposition sources” here refers to angles with respect to the origin point O at the center of the ridge waveguide top face 46a.

### Lifting-Off Step

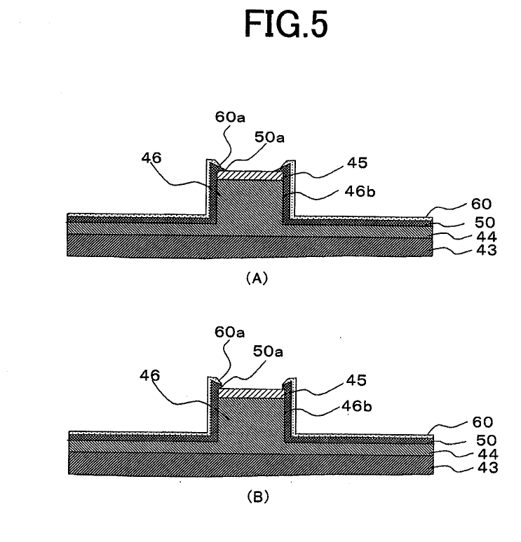

Next, in the step shown in FIG. 5A, the resist pattern 91 is removed by a process such as a wet etching with organic solvents, an ashing with oxygen gas, or a wet etching with a liquid mixture of sulfuric acid and hydrogen peroxide. As a result, the portions of the insulation film 50 and the metal film 60 that are formed on the resist pattern 91 are lifted-off, and the first opening 50a and the second opening 60a are thereby formed on the central portion of the ridge waveguide top face 46a. At this time, the first opening 50a is formed smaller in width than the second opening 60a.

### Insulation Film Etching Step

Next, in the step shown in FIG. 5B, the first opening 50a formed through the insulation film 50 is extended, by dry-etching or wet-etching the SiO₂ insulation film 50 alone using as a mask the metal film 60 formed on the insulation film 50, to substantially the same width as the second opening 60a formed through the metal film 60. In addition, applying a dry etching is favorable for the etching rather than a wet etching; in particular, a dry etching using SF₆ containing gas is desirable.

By thus etching the insulation film 50 using the metal film 60 as a mask, only the edges of the insulation film 50 that have been formed on the top face 46a of the ridge waveguide 46 can be self-adjustingly etched with accuracy without transferring a new pattern. Moreover, employing a dry etching enables only the edges of the insulation film 50 to be etched without eliminating the portions of the insulation film 50 that are formed on the side faces 46b of the ridge waveguide 46. Furthermore, employing a dry etching with SF₆, which causes relatively less damage, enables suppression of increase in the contact resistance and removal of organic substances such as resist scum that have been produced when transferring.

In particular, if the second opening 60a through the metal film 60 is formed having approximately the same width as the ridge waveguide 46 in the above-mentioned metal-film forming step, the width of the first opening 50a through the insulation film 50 can be extended to that of the ridge waveguide 46 by dry-etching the insulation film 50 using the metal film 60 as a mask.

### P-Side Electrode Forming Step

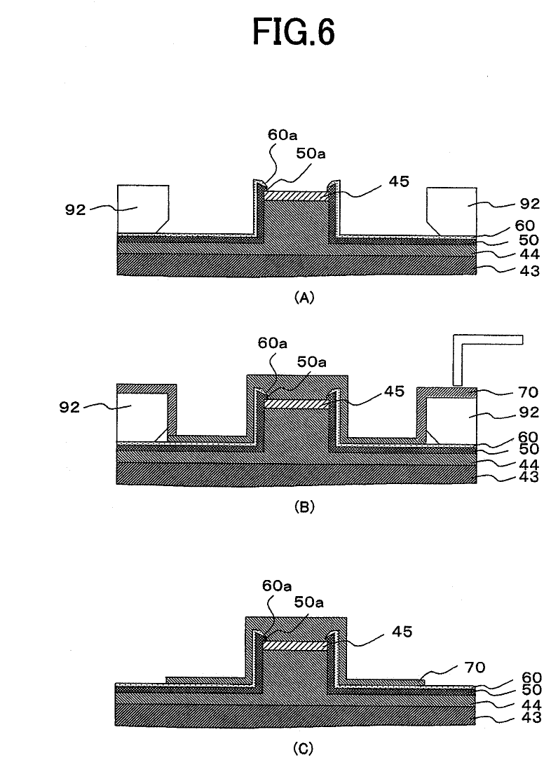

Next, resist pattern 92 composed of an image reversal resist is transferred, as shown in FIG. 6A, on the metal film 60 to form the p-side electrode 70. Then, the p-side electrode 70 is deposited, as shown in FIG. 6B, by vacuum deposition on the metal film 60 and the resist pattern 92, and on the p-contact layer 45 through the first and second openings 50a and 60a. Then, portions of the p-side electrode 70 that are formed on the resist pattern 92 are lifted off, as shown in FIG. 6C, by removing the resist pattern 92 using wet etching or the like with an organic solvent.

### N-Side Electrode Forming Step

Finally, in a not shown step, the rear surface is polished, and then, the n-side electrode 80 is formed on the rear surface of the n-GaN substrate 10. After that, the n-GaN substrate 10 is cleaved into laser diode chips.

Through the above steps, fabricated can be a semiconductor laser device 100 such as shown in FIG. 1 that is the semiconductor light-emitting device of Embodiment 1.

In this embodiment, since the metal film 60 is thus formed in such a manner that positional differences are formed between the edges of the insulation film 50 and those of the metal film 60 above the top face 46a of the ridge waveguide 46 by making use of the overhang-shaped cross-section resist pattern 91 formed on the ridge waveguide top face 46a, the width of the first opening 50a through the insulation film 50 can be easily extended without necessity of introducing another masking step, by etching the edges of the insulation film 50 on the ridge waveguide top face 46a using the metal film 60 as a mask. Hence, the contact area between a p-type contact layer 45 and the p-side electrode 70 can be readily increased without reducing yields in the lift-off step, so that a lower-voltage operable semiconductor laser device 100 can be realized.

Moreover, in the steps of forming the insulation film 50 and the metal film 60 by vacuum deposition, by setting larger the angle between the ridge waveguide top face 46a and the deposition source for the metal film 60 than that between the ridge waveguide top face 46a and the deposition source for the insulation film 50, the positional differences are easily formed between the edges of the metal film 60 and those of the insulation film 50. In particular, since the insulation film 50 has been deposited also on the side faces of the resist pattern 91 in the insulation film forming step, the deposition of the metal film 60 can be suppressed to enter into the space between the overhangs 91a, 91b of the resist pattern 91 and the ridge waveguide top face 46a, allowing the positional differences to be formed between the edges of the insulation film 50 and those of the metal film 60.

Furthermore, by forming the second opening 60a through the metal film 60 to have substantially the same width as the ridge waveguide 46, the first opening 50a through the insulation film 50 can be extended to approximately the same width as the ridge waveguide 46 in the insulation film forming step. Accordingly, the contact area between the p-side electrode 70 and the p-type contact layer 45 can be further increased, so that the operating voltage of the semiconductor laser device 100 can be further reduced.

Furthermore, since the p-side electrode 70 is formed of Pd, and the Au metal film 60 is formed between the p-side electrode 70 and the insulation film 50, the p-side electrode 70 and the metal film 60 can be improved in their mutual adherence, thereby preventing a conventional separation of the p-side electrode 70

Furthermore, since the contact area between the p-side electrode 70 and the p-type contact layer 45 can be readily increased as described above, even if the substrate 10, the n-type semiconductor layer 20, the active layer 30, and the p-type semiconductor layer 40 are formed of nitride semiconductors, the contact resistance between the p-side electrode 70 and p-type semiconductor layer 40 can be reduced.

In addition, while in this embodiment, the pattern 91 having the overhang shape in cross section is formed on the p-type semiconductor layer 40 (on the p-type contact layer 45) using an image reversal resist, there is no need to use such an image reversal type resist as long as its cross section can be formed in an overhang shape. An overhang-shaped cross-section resist pattern may be formed, for example, by using two kinds of resist having different etching rates formed in two layers in decreasing order of etching rates from the p-type semiconductor layer 40 and by etching selectively the sides of the faster etching-rate resist layer among the two resist layers.

While described in this embodiment has been the configuration of and its manufacturing method for the semiconductor laser device 100 in which only the ridge waveguide 46 is formed on the p-type semiconductor layer 40, the configuration and the manufacturing method can also be applied to a semiconductor light-emitting device in which an electrode-pad base is formed on its p-type semiconductor layer 40.

As described above, according to this embodiment, a method of manufacturing a semiconductor light-emitting device includes: a resist forming step of forming the overhang-shaped cross-section resist pattern 91 in the predetermined position on the second conductivity type, i.e., the p-type semiconductor layer 40; a ridge forming step of forming the ridge waveguide 46 in the p-semiconductor layer 40 by etching it using the resist pattern 91 as a mask; an insulation film forming step of forming, on the resist pattern 91 and the p-semiconductor layer 40, the insulation film 50 having the first opening 50a on a portion of the top face 46a of the ridge waveguide 46; a metal film forming step of forming on the insulation film 50 the metal film 60 having the second opening 60a whose width is larger than that of the first opening 50a; a lift-off step of lifting-off, by removing the resist pattern 91, the insulation film 50 and the metal film 60 having been formed on the resist pattern 91; an insulation film etching step of etching, by using the metal film 60 as a mask, edges of the insulation film 50 having been formed on the ridge waveguide 46; and a metal electrode forming step of forming the metal electrode, i.e., the p-side electrode 70 on the p-semiconductor layer 40. Thereby, the first opening self-adjusts to the second opening, so that the contact area between the p-semiconductor layer 40 and the p-side electrode 70 can be readily increased. Therefore, a semiconductor light-emitting device can be realized that operates at lower voltage.

### Embodiment 2

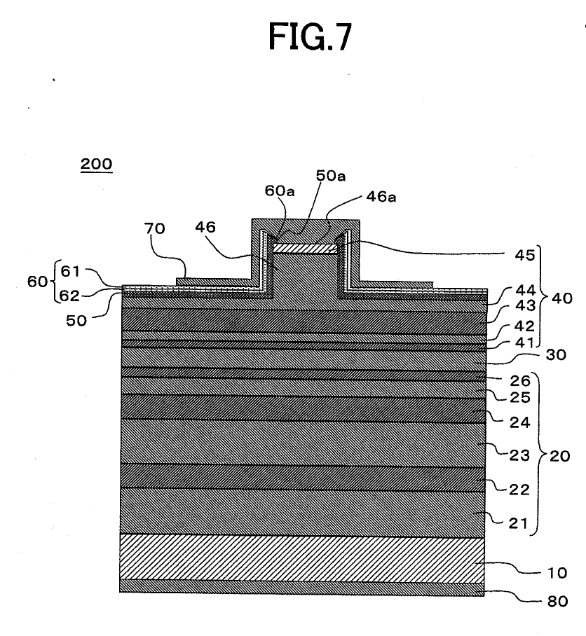

FIG. 7 is a cross sectional view illustrating a configuration of a semiconductor light-emitting device in Embodiment 2 of the invention. Whereas in the semiconductor light-emitting device of Embodiment 1, its metal film 60 is composed of a single-layer metal film, in the semiconductor light-emitting device of Embodiment 2, its metal film 60 is composed of multi-layer metal films.

A semiconductor laser device 200 shown in FIG. 7 is the semiconductor light-emitting device of Embodiment 2. The metal film 60 formed therein is composed of two layers of a first metal film 61 that is in contact with the p-side electrode 70 made of Pd and a second metal film 62 that is in contact with the insulation film 50 made of SiO₂. Here, the first metal film 61 is made of Au, and the second metal film 62 is made of Cr or Ti. Hence, an alloy layer of Au and Ti, or Au and Cr may be formed in the interfacial surface between the first metal film 61 and the second metal film 62. Except for these points, the semiconductor laser device 200 of Embodiment 2 has a configuration similar to the semiconductor laser device 100 of Embodiment 1. The first and the second metal films 61, 62 are therefore formed in a step similar to the metal film forming step described in Embodiment 1.

Thus, by forming of Au the first metal film 61 in contact with the p-side Pd electrode 70, the p-side electrode 70 and the metal film 60 can be improved in their mutual adherence. Moreover, by forming of Cr or Ti the second metal film 62 in contact with the SiO₂ insulation film 50, the metal film 60 and the insulation film 50 can also be improved in their mutual adherence, preventing the insulation film 50 and the metal film 60 from separating from each other.

While the metal film 60 is formed of two layers of the first metal film 61 and the second metal film 62 in this embodiment, the metal film 60 may be further composed of a single-layer metal film or multi-layer metal films formed between the first and the second metal films 61, 62 made of the above-mentioned materials.

As described above, according to this embodiment, since the metal film 60 is formed of the first metal film 61 that is in contact with the p-side Pd electrode 70 and of the second metal film 62 that is in contact with the SiO₂ insulation film 50, and the first and the second metal films 61, 62 are made of Au, and Cr or Ti, respectively, the metal film 60 can be improved in its adherence to the p-side electrode 70 and the insulation film 50, in addition to the effects described in Embodiment 1, preventing the p-side electrode 70 from separation.

### Embodiment 3

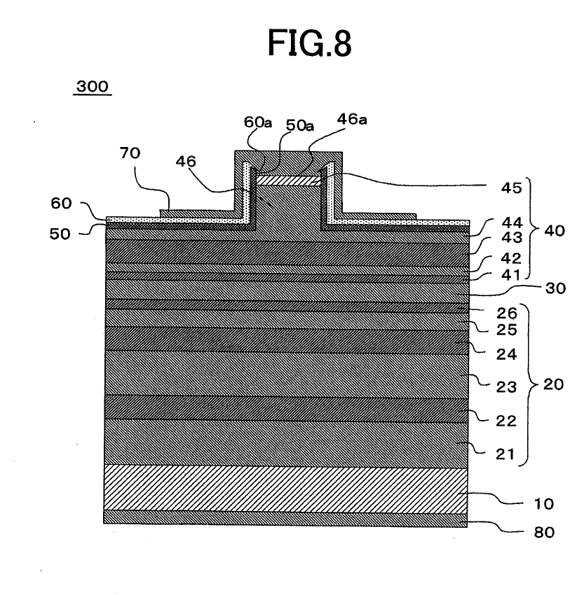

FIG. 8 is a cross sectional view illustrating a configuration of a semiconductor light-emitting device in Embodiment 3 of the invention. A semiconductor laser device 300 shown in FIG. 8 is the semiconductor light-emitting device of Embodiment 3. The width of the first opening 50a formed through the insulation film 50 is larger than that of the second opening 60a formed through the metal film 60. Except for this point, the semiconductor laser device 300 has a configuration similar to the semiconductor laser device 100 of Embodiment 1. Manufacturing steps for the semiconductor laser device 300 other than a later-described insulation film etching step are similar to those described in Embodiment 1; hence, their explanations are omitted.

In the insulation film etching step, while the SiO₂ insulation film 50 is dry-etched or wet-etched using the metal film 60 as a mask, which is similar to Embodiment 1, the etching time of the insulation film 50 in this embodiment is set longer than that in Embodiment 1, to make larger the width of the first opening 50a through the insulation film 50 than that of the second opening 60a through the metal film 60.

Thus, by making larger the width of the first opening 50a than that of the second opening 60a, the contact area between the p-side electrode 70 and the p-type contact layer 45 can be increased, permitting reduction of the operating voltage of the semiconductor laser device 300. Moreover, making larger the width of the first opening 50a than that of the second opening 60a allows providing a margin for the etching condition in the insulation film etching step, resulting in improvement in the rate of conforming product in the etching step.

As described above, according to this embodiment, since the semiconductor laser device 300 is fabricated such that the width of the first opening 50a formed through the insulation film 50 is made larger than that of the second opening 60a formed through the metal film 60, the operating voltage of the semiconductor laser device 300 can be reduced and the rate of conforming product in the insulation film etching step can be improved.

1. A method of manufacturing a semiconductor light-emitting device comprising:
forming successively on a substrate, a first conductivity type semiconductor layer, an active layer, and a second conductivity type semiconductor layer;
forming a resist pattern having an overhanging shape, in cross section, in a predetermined position on the second conductivity type semiconductor layer;
forming a ridge waveguide in the second conductivity type semiconductor layer by etching the second conductivity type semiconductor layer, using the resist pattern as a mask;
forming, on the resist pattern and the second conductivity type semiconductor layer, an insulating film having a first opening located on a portion of a top face of the ridge waveguide, using the resist pattern;
forming on the insulating film a metal film having a second opening with a width larger thanes width of the first opening;
lifting off, by removing the resist pattern, portions of the insulating film and the metal film located on the resist pattern;
etching, using the metal film as a mask, edges of the insulating film on the ridge waveguide; and
forming a metal electrode on the metal film, and on the second conductivity type semiconductor layer, through the first and the second openings.

2. The method of manufacturing a semiconductor light-emitting device, as set forth in claim 1, wherein the first opening self-adjusts to the second opening.

3. The method of manufacturing a semiconductor light-emitting device, as set forth in claim 1, wherein the width of the second opening is substantially the same as width of the ridge waveguide.

4. The method of manufacturing a semiconductor light-emitting device, as set forth in claim 1, wherein the first conductivity type semiconductor layer, the active layer, and the second conductivity type semiconductor layer are nitride semiconductors.

5. The method of manufacturing a semiconductor light-emitting device, as set forth in claim 1, wherein the metal film includes a first metal film that is in contact with the metal electrode and a second metal film that is in contact with the insulating film.

6. The method of manufacturing a semiconductor light-emitting device, as set forth in claim 5, wherein:
the insulating film is silicon oxide;
the metal electrode is palladium;
the first metal film gold; and
the second metal film chromium or titanium.

7. The method of manufacturing a semiconductor light-emitting device, as set forth in claim 1, including forming the insulating film and the metal film in respective vacuum depositions, where an angle between the top face of the ridge waveguide and a deposition source for the metal film is larger than the angle between the top face of the ridge waveguide and a deposition source for the insulating film.

8. A semiconductor light-emitting device comprising:
a substrate;
a first conductivity type semiconductor layer on the substrate;
an active layer on the first conductivity type semiconductor layer;
a second conductivity type semiconductor layer on the active layer and having a ridge waveguide that projects outwards with respect to the active layer;
an insulating film on the second conductivity type semiconductor layer and having a first opening that opens on a top face of the ridge waveguide;
a metal film on the insulating film and having a second opening that communicates with the first opening and a width narrower than the first opening; and
a metal electrode electrically connected to the second conductivity type semiconductor layer through the first and second openings.

9. The semiconductor light-emitting device as set forth in claim 8, wherein the first opening self-adjusts to the second opening.

10. The semiconductor light-emitting device as set forth in claim 8, wherein width of the second opening is substantially the same as width of the ridge waveguide.

11. The semiconductor light-emitting device as set forth in claim 8, wherein the first conductivity type semiconductor layer, the active layer, and the second conductivity type semiconductor layer are nitride semiconductors.

12. The semiconductor light-emitting device as set forth in claim 8, wherein the metal film includes a first metal film that is in contact with the metal electrode and a second metal film that is in contact with the insulating film.

13. The semiconductor light-emitting device as set forth in claim 12, wherein:
the insulating film is silicon oxide;
the metal electrode is palladium);
the first metal film is gold; and
the second metal film is chromium or titanium.
